(19) United States
(12) Patent Application Publication
(10) Pub. No.: US 2003/0088388 A1
(43) Pub. Date: May 8, 2003

(54) Unit converting apparatus

(76) Inventors: Kenichi Miyazaki, Chiba-shi (JP); Kazuko Yamanoi, Satte-shi (JP)

Correspondence Address: ADAMS & WILKS, 31st Floor, 50 Broadway, New York, NY, 10004, US

(21) Appl. No.: 10/269,273

(22) Filed: Oct. 11, 2002

(30) Foreign Application Priority Data
Oct. 12, 2001 (JP) 2001-315294

(51) Int. Cl. H03F 1/26; H04B 15/00; G06F 15/00

(52) U.S. Cl. 702/198

(57) ABSTRACT

A unit converting apparatus for handling units used in wide areas only supported a conversion rate of one area, and a plurality of types of apparatuses were necessary even when handling units of the same name. Conversion rate difference data corresponding to each area is added to conversion rate data in advance and unit conversion is carried out using only a conversion rate of a designated area. The designation of an area can be set by a user using an external switch or the like.

### BACKGROUND OF THE INVENTION

1. Field of the Invention

This invention relates to a unit converting apparatus for converting a value of a certain unit inputted by a user into a value of another unit,

2. Description of the Related Art

For example, in a unit converting apparatus used in Britain and the United States, a conversion value may differ between Britain and the United States. For example, “1 gallon” is “4.546 liters in Britain while it is “3.785 liters” in the United States.

Conventionally, an apparatus dedicated for conversion into either the UK unit or the US unit was selected and used, or both units were included in an apparatus and expressed as “Gallon (UK)” and “Gallon (US)”, which were handled as two types of units.

Therefore, manufacturers had to manufacture a plurality of types of apparatuses because of the difference in the value of a certain conversion rate, though these apparatuses had approximately the same functions. This invention can significantly reduce the manufacturing cost and the inventory risk due to the foregoing situation.

Moreover, if both of units having the same name but having different conversion rates are used and these are handled as different types of units, users must select one of many units and are forced to carry out redundant operations.

### SUMMARY OF THE INVENTION

In order to solve the foregoing problem, an aspect of this invention resides in a unit converting apparatus characterized by comprising, an external input means for carrying out at least numerical data input and various control input, a unit data storage means in which a plurality of conversion rate data including data having conversion rate difference information are stored, a user selection storage means for storing a selected area inputted from the external input means, a conversion selection means for selecting conversion rate data corresponding to the selected area stored in the user selection storage means based on the conversion rate difference information, a conversion means for calculating a conversion value from the numerical data inputted from the external input means and the conversion rate data selected by the conversion selection means, and a display means for displaying the calculated conversion value.

### BRIEF DESCRIPTION OF THE DRAWINGS

FIG. 1 is a flowchart of a unit conversion function in a unit converting of an embodiment according to this invention

FIG. 2 is a flowchart of area selection used by a user in the unit converting apparatus of the embodiment according to this invention.

FIG. 3 is a functional structural block diagram of the unit converting apparatus of the embodiment according to this invention.

FIG. 4 is a schematic structural view of the unit converting apparatus of the embodiment according to this invention.

FIG. 5 is a view showing the display state of an area selection screen in the unit converting apparatus of the embodiment according to this invention.

FIG. 6 is a view showing the display state of the unit conversion result in the case where “Liter→Gallon” is selected, in the unit converting apparatus of the embodiment according to this invention.

FIG. 7 shows an exemplary conversion rate data list in the unit converting apparatus of the embodiment according to this invention.

### DESCRIPTION OF THE PREFERRED EMBODIMENT

This invention enables switching of the conversion rate of a unit by users selection in a unit converting apparatus for handling units which are used relatively broadly, such as a unit having different conversion rates for the same name because of the difference in area or the like.

Hereinafter, an embodiment of this invention will be described in detail with reference to the drawings.

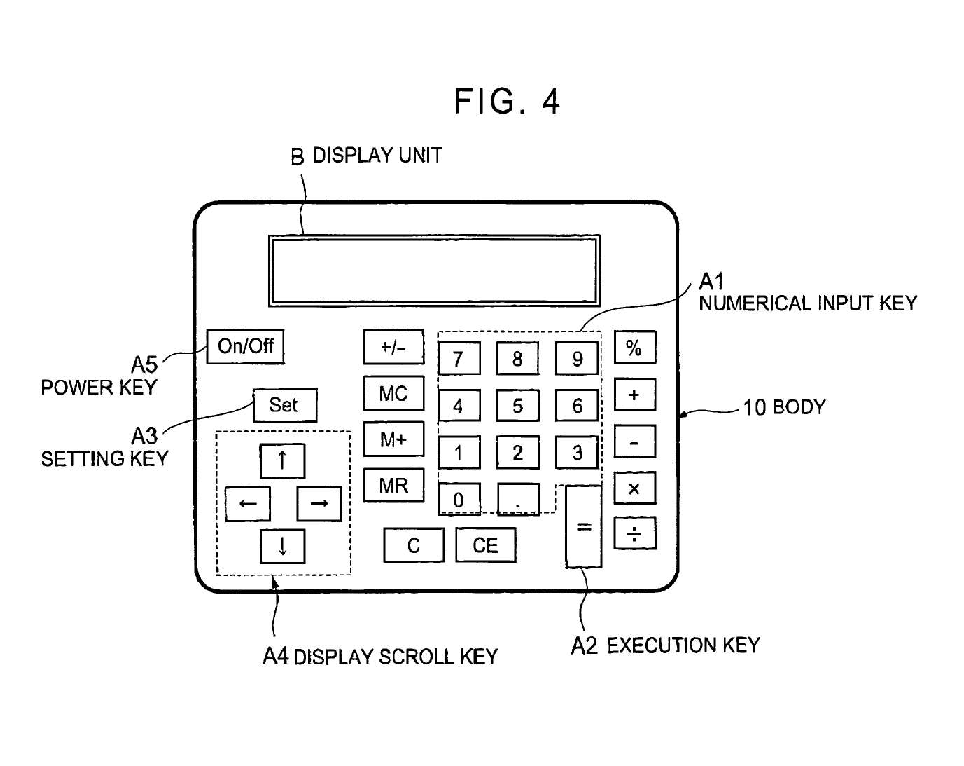

FIG. 4 is a schematic view of a unit converting apparatus based on an embodiment of this invention.

A numerical input key A1 is used by a user to input a numerical value or the like. An execution key A2 is used for notifying the apparatus of the decision of an input after the user selection or input of characters or the like. A setting key A3 is used for displaying a mode of each setting on the apparatus when the user wants to carry out each setting of the apparatus. A power key A5 is used by the user to turn on or off the power of the apparatus. These are equivalent to external input means.

A display unit B is equivalent to display means for visually displaying the users input or the output of the apparatus.

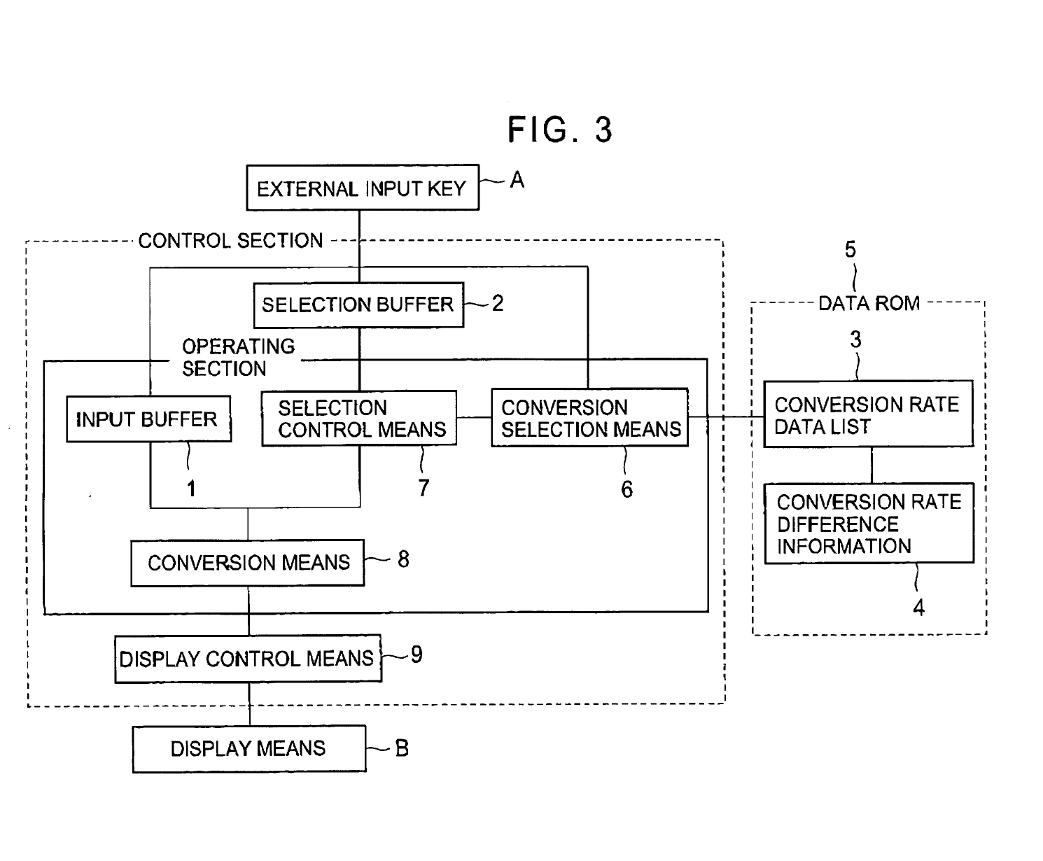

FIG. 3 is a functional structural block diagram of the unit converting apparatus based on the embodiment of this invention.

In this embodiment, the setting key A3, a display scroll key A4 and the execution key A2 of the external input keys A are used for setting which conversion rate is used by the user to perform unit conversion, and the result of this setting is stored into a selection buffer 2, which is equivalent to user selection storage means. Moreover, the numerical input key Al and the execution key A2 are used for inputting a numerical value on which the user wants to perform unit conversion, and the result of this is stored into an input buffer 1, which is equivalent to an input buffer memory.

When actually performing unit conversion, conversion selection means 6 takes out conversion rate data for converting the numerical value stored in the input buffer 1, from a unit data list 3 in a data ROM 5. The data ROM 5 is equivalent to unit data storage means.

If conversion rate difference information 4 has been added to the conversion rate data, selection control means 7 selects a conversion rate corresponding to the user's selection stored in the selection buffer 2 from the conversion rate data. If the conversion rate difference information 4 has not been added, also the selection control means 7 selects the conversion rate selected by the conversion selection means 6.

Conversion means 8 performs conversion based on the numerical value stored in the input buffer 1 and the conversion rate selected by the selection control means 7.

The result of the conversion by the conversion means 8 is transformed to display data by display control means 10 and displayed on the display means B.

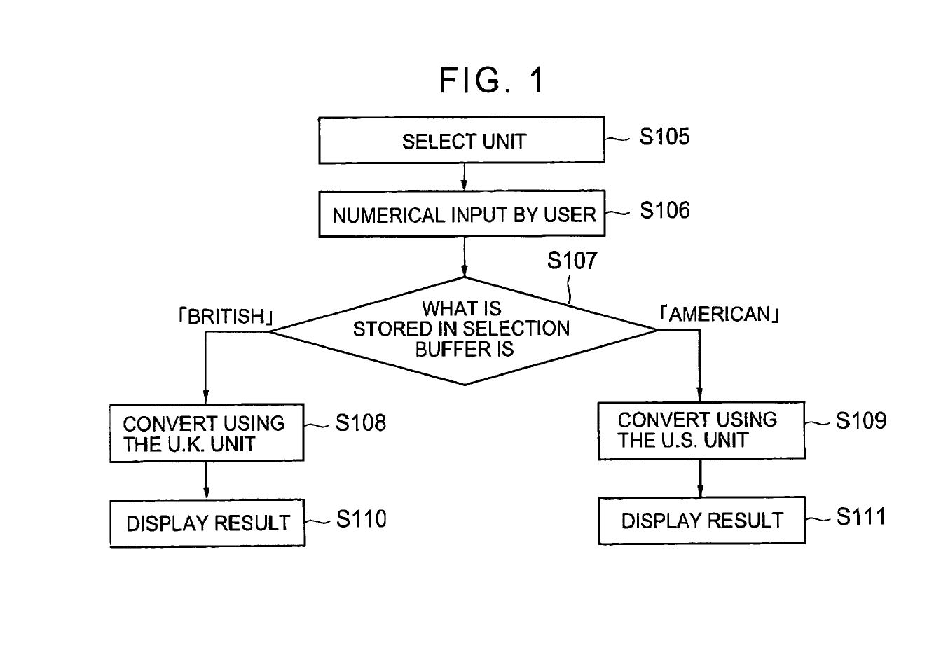

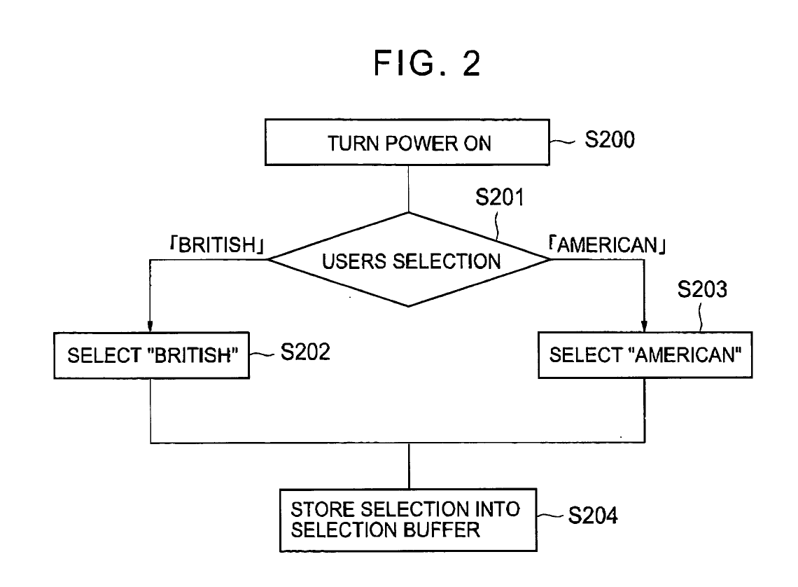

Now, the operation principle in the case of performing unit conversion using a unit converting apparatus which handles U.K. and U.S. conversion rates will be specifically described in accordance with the flowcharts of FIGS. 1 and 2.

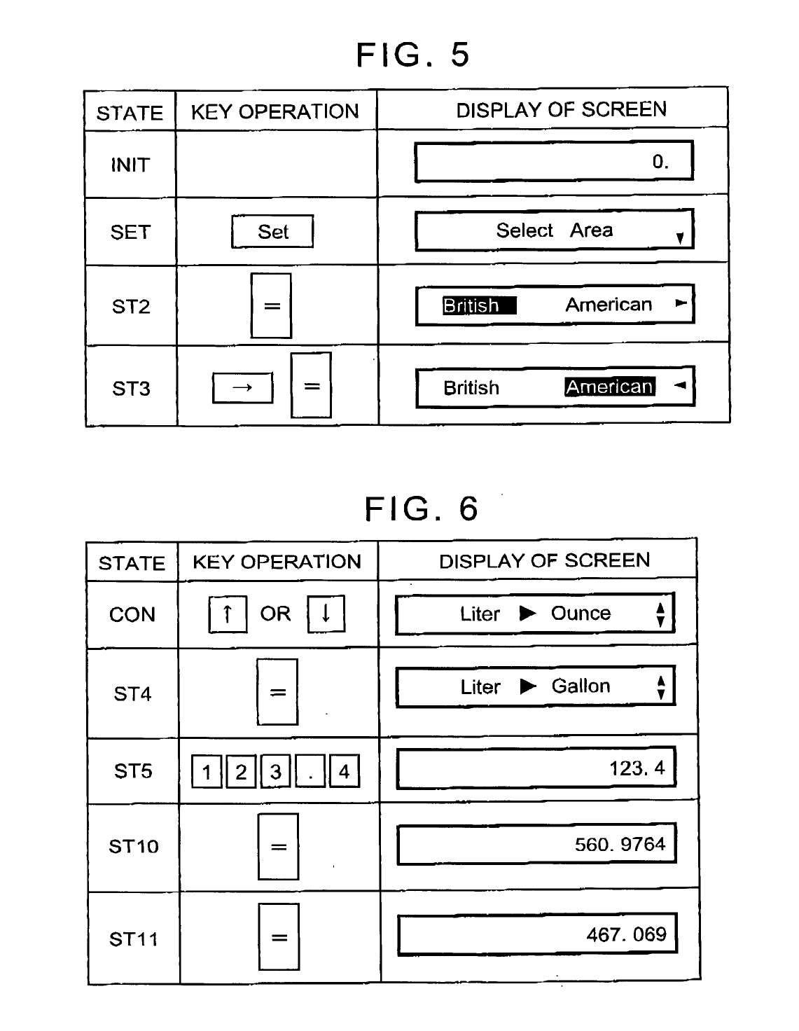

FIGS. 5 and 6 show the state of the display unit at each step.

The user needs to select which of the U.K. and U.S. conversion rates is to be used before carrying out unit conversion in accordance with the procedure shown in the flowchart of FIG. 2.

First, by pressing the setting key A3 in an input standby state (step S200, display: state INIT in FIG. 5) immediately after pressing the power key A5 or the like, the user can carry out each setting such as selection of an area where the unit to be handled is used (display: state SET in FIG. 5). In this case, the user can select a setting item by using the display scroll key A4 and decide the setting item by using the execution key A2.

Next, the user can select a setting area by using the display scroll key A4 and decide the setting area by using the execution key A2 (step S201, display; states ST2 and ST3 in FIG. 5). If the execution key A2 is pressed when the display is in a state ST2 in FIG. 5, the unit to be handled is set to the “British” unit (U.K. conversion rate) (step S202). If the execution key A2 is pressed when the display is in a state ST3, the unit to be handled is set to the “American” unit (U.S. conversion rate) (step S203). The setting is stored into the selection buffer 2 (step S204).

An exemplary case where the user converts “123.4 liters” into “gallon” will now be described with reference to the procedure shown in the flowchart of FIG. 1.

First, the user selects conversion which the user wants to carry out from a plurality of conversion items by using the display scroll key A4 (display state CON in FIG. 6) and decides the conversion by using the execution key A2 (step S205). If the execution key A2 is pressed on the screen of the state CON in FIG. 6, the conversion of “Liter” into “Ounce” is set. In this embodiment, as the user wants to convert “liter” into “gallon”, the user presses the execution key A2 in a state ST4 in FIG. 6, thus setting the conversion of “Liter” into Gallon”. In this case, the conversion selection means 6 selects conversion rate data from a conversion rate data list in the data ROM 5.

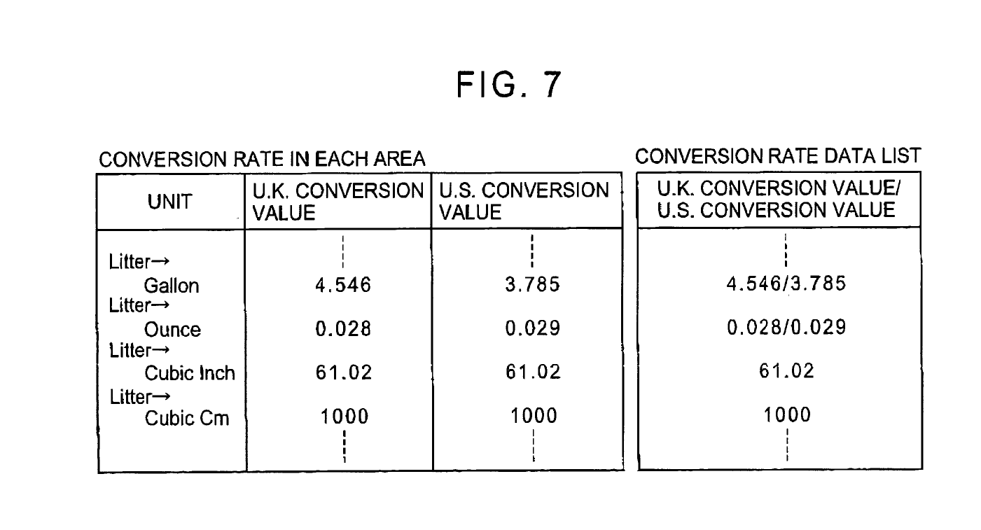

FIG. 7 is an exemplary conversion rate data list including the conversion rate in each area and the conversion rate data list 3 with the conversion rate difference information 4 added thereto. In the unit data list 3, for a unit having different conversion rates for the same name between the U.K. and the U.S., a special mark “/” is added between these conversion rates. This special mark “/” is equivalent to the conversion rate difference information. In this case, the conversion rate list as shown in FIG. 7 need be stored in the data ROM 5.

In this embodiment, the conversion selection means 6 selects “4.546/3.875” of “Liter→Gallon”.

Next, the user inputs “123.4” by using the numerical input key (step S106, display; state ST5 in FIG. 6). As the user presses the execution key A2, “123.4”, is stored into the input buffer 1.

Then, the selection control means 7 confirms the content stored in the selection buffer 2 (step S207).

If the content stored in the selection buffer 2 is “British” (step S108), the selection control means 7 selects “4.546” and conversion is carried out based on that conversion rate. “4.546”, which is a “British” gallon, is calculated and the result is displayed on the display means B by using the display control means 9 (step S110, display! state ST10 in FIG. 6).

If the content stored in the selection buffer 2 is “American” (step S109), the selection control means 7 selects “3.785” and conversion is carried out based on that conversion rate. “3.785”, which is a “American” gallon, is calculated and the result is displayed on the display means B by using the display control means 9 (step S111, display; state ST11 in FIG. 6).

In the unit converting apparatus of this embodiment, when handling a unit having different spellings for the same unit because of the difference in area or the like, spelling difference information is added to the unit name, thus enabling conversion with a unit name required by the user.

As described above, according to this invention, since means for enabling the user to select which areas conversion rate is to be used for unit conversion is provided for the conversion rate data in advance, the unit conversion function using only the conversion rate of the area required by the user can be executed. Therefore, a unit converting apparatus which is applicable to users of a plurality of areas with a single type of apparatus can be provided and the manufacturing cost and the inventory risk in developing products for a plurality of areas can be significantly reduced.

What is claimed is:

1. A unit converting apparatus comprising:
an external input means for carrying out at least numerical data input and various control input;
a unit data storage means in which a plurality of conversion rate data including data having conversion rate difference information are stored;
a user selection storage means for storing a selected area inputted from the external input means;
a conversion selection means for selecting conversion rate data corresponding to the selected area stored in the user selection storage means based on the conversion rate difference information;
a conversion means for calculating a conversion value from the numerical data inputted from the external input means and the conversion rate data selected by the conversion selection means; and
a display means for displaying the calculated conversion value.

2. A unit converting apparatus according to claim 1, wherein if a single unit name has partially different spellings because of the difference in area or the like, the unit name is displayed with its spelling switched in accordance with the selected area stored in the user selection storage means.
